(19) United States
(12) Patent Application Publication
(10) Pub. No.: US 2026/0344451 A1
(43) Pub. Date: Oct. 29, 2026

(54) SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 19/309,644

(22) Filed: Aug. 26, 2025

(30) Foreign Application Priority Data
Apr. 29, 2025 (KR) 10-2025-0056410

(51) Int. Cl. H10W 46/00; H10P 54/00; H10W 42/00

(52) U.S. Cl. CPC H10W 46/00; H10P 54/00; H10W 42/121; H10W 46/301; H10W 46/503

(57) ABSTRACT

A semiconductor device includes: a substrate including a chip region and a scribe lane region disposed outside the chip region; an insulating structure disposed on the substrate; a plurality of trench segments disposed to penetrate the insulating structure in the scribe lane region, and arranged, in first areas, along a first direction parallel to a first boundary between the chip region and the scribe lane region; and a conductive layer at least partially overlapping the insulating structure in second areas between the first areas.

### CROSS-REFERENCE TO RELATED APPLICATIONS

The present application claims priority under 35 U.S.C. 119(a) to Korean patent application number 10-2025-0056410 filed on Apr. 29, 2025, which is incorporated herein by reference in its entirety.

### BACKGROUND

### 1. Technical Field

Embodiments of the present disclosure relate to a semiconductor device.

### 2. RELATED ART

Semiconductor devices have emerged as key components in the electronics industry based on characteristics of the semiconductor devices such as miniaturization, multifunctionality, and/or low manufacturing cost. As the electronics industry continues to advance, semiconductor devices are increasingly required to achieve high integration.

To meet the demand for high integration, semiconductor devices may include a redistribution layer (RDL) pattern. The redistribution pattern may be electrically connected to chip pads and may extend from a region where the chip pads are disposed to other regions.

### SUMMARY

The objects addressed by the embodiments of the present disclosure are not limited to those mentioned herein, and other objects not mentioned will be clearly understood by those skilled in the art based on the following descriptions.

Embodiments of the present disclosure may provide a semiconductor device capable of preventing degradation of device characteristics caused by process defects.

Embodiments of the present disclosure may provide a semiconductor device including: a substrate including a chip region and a scribe lane region disposed outside the chip region; an insulating structure disposed on the substrate; a plurality of trench segments disposed to penetrate the insulating structure in the scribe lane region, and arranged, in first areas, along a first direction parallel to a first boundary between the chip region and the scribe lane region; and a conductive layer at least partially overlapping the insulating structure in second areas between the first areas.

Embodiments of the present disclosure may provide a semiconductor device comprising: a substrate including a chip region and a scribe lane region disposed outside the chip region; an insulating structure disposed on the substrate; a plurality of trench segments disposed in the scribe lane region at a same level as the insulating structure, and arranged, in first areas, along a first direction parallel to a first boundary between the chip region and the scribe lane region; and a conductive layer disposed on the insulating structure in the scribe lane region. The conductive layer may include: a first portion disposed between the first boundary and second boundary, and spaced farther from a second boundary than the plurality of trench segments, the first portion extending in a direction parallel to the first direction, the second boundary being disposed apart from the first boundary in the scribe lane region; and a second portion at least partially overlapping the insulating structure in second areas between the first areas.

According to embodiments of the present disclosure, degradation of device characteristics in a semiconductor device due to process defects may be prevented.

The effects of the embodiments of the present disclosure are not limited to those described above, and additional effects not mentioned will be clearly understood by those skilled in the art based on the appended claims.

### BRIEF DESCRIPTION OF THE DRAWINGS

The present disclosure will be more fully understood from the following detailed description and the accompanying drawings, which are provided solely for illustrative purposes and are not intended to limit the scope of the present disclosure.

FIG. 1 is a view illustrating a wafer in which semiconductor devices according to embodiments of the present disclosure are integrated.

FIG. 2 is a plan view illustrating an embodiment of a semiconductor device, showing an enlarged view of region A in FIG. 1.

FIG. 3 illustrates cross-sectional views of portions I–I′ and II–II′ of FIG. 2.

FIGS. 4-6 are cross-sectional views illustrating a method of manufacturing a semiconductor device according to the embodiment disclosed in FIG. 2.

FIGS. 7 and 8 are plan views illustrating a method of manufacturing a semiconductor device according to the embodiment disclosed in FIG. 2, showing an enlarged view of region B in FIG. 2.

FIG. 9 is a plan view illustrating another embodiment of the semiconductor device disclosed in FIG. 1, showing an enlarged view of region A in FIG. 1.

FIG. 10 is a view illustrating a cross-sectional structure of portion I–I′ in FIG. 8.

FIG. 11 is a plan view illustrating a method of manufacturing a semiconductor device according to the embodiment disclosed in FIG. 8, showing an enlarged view of region B in FIG. 8.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, and “comprising” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element "is connected or coupled to", “contacts or overlaps” etc., a second element, it should be interpreted that, not only can the first element “be directly connected or coupled to” or “directly contact or overlap” the second element, but a third element can also be "interposed" between the first and second elements, or the first and second elements can "be connected or coupled to", “contact or overlap”, etc., each other via a fourth element. Here, the second element may be included in at least one of two or more elements that "are connected or coupled to", “contact or overlap”, etc., each other.

When time relative terms, such as "after," "subsequent to," "next," "before," and the like, are used to describe processes or operations of elements or configurations, or flows or steps in operating, processing, manufacturing methods, these terms may be used to describe non-consecutive or non-sequential processes or operations unless the term "directly" or "immediately" is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to accompanying drawings.

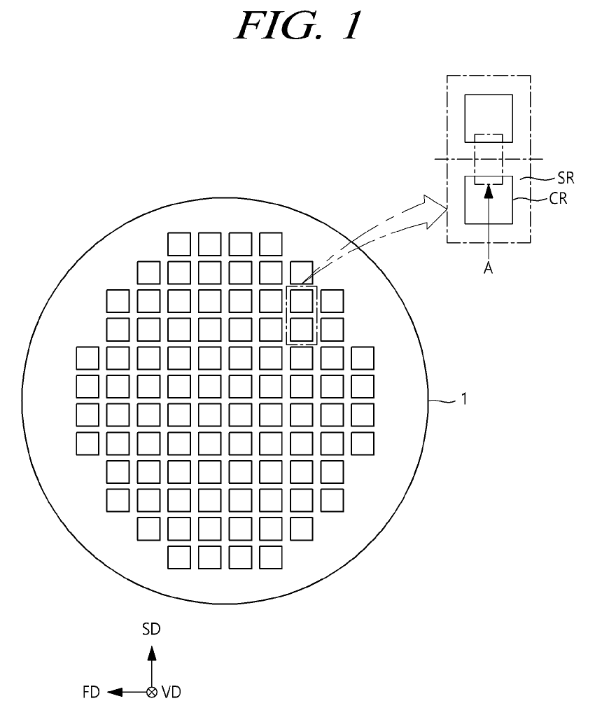

FIG. 1 is a view illustrating a wafer 1 in which semiconductor devices according to embodiments of the present disclosure are integrated.

Referring to FIG. 1, the wafer 1 may include a chip region CR and a scribe lane region SR.

The chip region CR may be a region that becomes an individual semiconductor chip after the wafer 1 is diced. Each chip region CR may include integrated circuits to function as an individual semiconductor chip.

A direction parallel to the boundary between the chip region CR and the scribe lane region SR may be defined as a first direction FD. A direction intersecting the first direction FD may be defined as a second direction SD. The first direction FD and the second direction SD may be substantially perpendicular to each other.

The scribe lane region SR may extend to surround the sides of each chip region CR in the first direction FD and the second direction SD, intersecting each other. The scribe lane region SR may be continuous with the chip region CR and located outside the chip region CR. The wafer 1 may be diced along a cutting line in the scribe lane region SR using a laser, blade, or the like. In one embodiment, the cutting line may be parallel to the first direction FD or the second direction SD.

A portion of the wafer 1 may include a semiconductor device and a semiconductor device adjacent thereto. A region between the semiconductor device and the adjacent semiconductor device may be defined as region A.

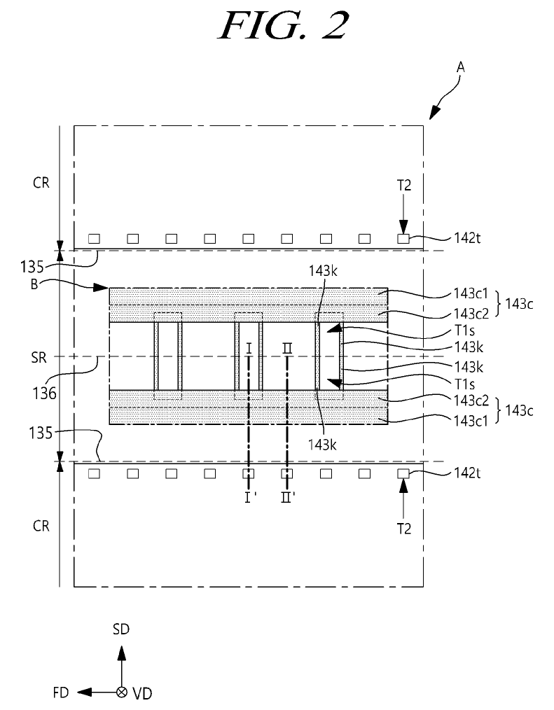

FIG. 2 is a plan view illustrating an embodiment of a semiconductor device, showing an enlarged view of region A in FIG. 1.

Region A may include a portion of the semiconductor device and a portion of the adjacent semiconductor device (i.e., a portion of two adjacent semiconductor devices).

Referring to FIG. 2, the semiconductor device may include the chip region CR and a portion of the scribe lane region SR that is continuous with the chip region CR.

The scribe lane region SR may include a first boundary 135 that is in contact with the chip region CR. For example, the first boundary 135 may be a boundary between the scribe lane region SR and the chip region CR. The first boundary 135 may be parallel to the first direction FD. The scribe lane region SR may further include a second boundary 136 spaced apart from and located outward of the first boundary 135. The second boundary 136 may also be parallel to the first direction FD.

An alignment key region B may be disposed in a portion of the scribe lane region SR. The alignment key region B may be defined as a region in which a redistribution align key is disposed. The redistribution align key may be used for alignment during the etching of a redistribution pattern layer in the semiconductor device manufacturing process.

The alignment key region B may be located between adjacent chip regions CR. In FIG. 2, the alignment key region B is shown as being located between chip regions CR that are adjacent to each other in the second direction SD, but the position of the alignment key region B is not limited thereto.

A plurality of first trench segments T1s may be disposed in the alignment key region B. The first trench segments T1s may be part of a first trench (not shown). The plurality of first trench segments T1s may be arranged along the first direction FD.

An alignment pattern layer 143k may be disposed inside the first trench segments T1s. In one embodiment, the alignment pattern layer 143k may be part of the redistribution align key.

A conductive layer 143c may be disposed in the alignment key region B. The conductive layer 143c may be disposed on the same layer in which the first trench segments T1s are disposed. The plurality of first trench segments T1s may be located between one end and the other end of the conductive layer 143c. The conductive layer 143c may include a first portion 143c1 and a second portion 143c2. The second portion 143c2 may be continuous with the first portion 143c1.

The first portion 143c1 may be disposed between regions of the layer where the plurality of first trench segments T1s are disposed and the chip region CR. The first portion 143c1 may be located between the first boundary 135 and the second boundary 136. The first portion 143c1 may be spaced farther from the second boundary 136 than the plurality of first trench segments T1s. The first portion 143c1 may extend in a direction parallel to the first direction FD. The first portion 143c1 may be disposed in a region other than the regions where the plurality of first trench segments T1s are disposed.

At least a portion of the second portion 143c2 may be disposed between areas of the layer where the first trench segments T1s are arranged. The second portion 143c2 may be located between the first portion 143c1 and the second boundary 136. The second portion 143c2 may extend along the first direction FD. The second portion 143c2 may at least partially overlap the plurality of first trench segments T1s. The second portion 143c2 may completely cover side surfaces of the respective first trench segments T1s that face the chip region CR.

A width of the second portion 143c2 in the first direction FD may be equal to a width of the first portion 143c1 in the first direction FD. The second portion 143c2 may be positioned between the first boundary 135 and the second boundary 136. The second portion 143c2 may be spaced farther from the second boundary 136 than the first trench segments T1s.

Since the first trench segments T1s are disposed in a direction perpendicular to the dicing direction, abnormal dicing may occur. Due to such abnormal dicing, a sidewall of the semiconductor chip may be formed in a coarse shape, which may result in defects such as delamination or cracks during a subsequent packaging process. In the present embodiments, because the conductive layer 143c is disposed closer to the chip region CR than the first trench segments T1s, abnormal dicing can be suppressed and the straightness of the dicing line can be improved. At least a portion of the second portion 143c2 is disposed between adjacent first trench segments T1s, thereby enabling control of abnormal dicing. Furthermore, because the conductive layer 143c is spaced apart from the location where dicing proceeds, even if the dicing position varies, abnormal dicing may still be controlled.

A second trench T2 may be disposed in the chip region CR. A redistribution trench portion 142t may be disposed in the chip region CR. The redistribution trench portion 142t may be located over the second trench T2.

Although FIG. 2 illustrates a limited number of second trenches T2, the present disclosure is not limited thereto, and various numbers of second trenches T2 may be provided. Although FIG. 2 illustrates the second trenches T2 as being disposed parallel to the first direction FD, the present disclosure is not limited thereto.

A redistribution pad portion (not shown) may be disposed in the chip region CR. The redistribution pad portion (not shown) may be continuous with the redistribution trench portion 142t. The redistribution pad portion (not shown) may be electrically connected to a chip pad (not shown).

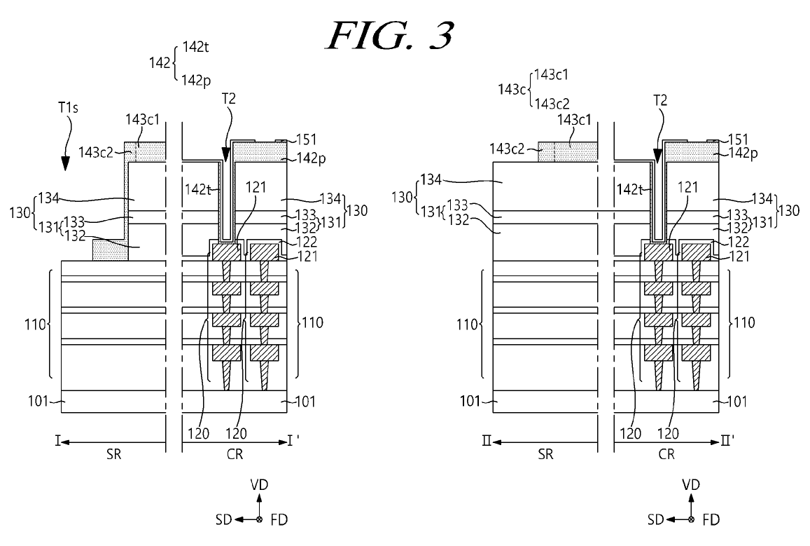

FIG. 3 is a view illustrating cross-sectional examples of portions I-I’ and II-II’ of FIG. 2.

Referring to FIG. 2 and 3, a device layer 110 may be disposed on a substrate 101. A wiring structure 120 may be disposed on the substrate 101.

The substrate 101 may include a semiconductor substrate such as a silicon wafer or a silicon-on-insulator (SOI) wafer. The substrate 101 may include a group III-V compound semiconductor substrate, for example, a gallium arsenide (GaAs) substrate. The substrate 101 may include single-crystal silicon, polysilicon, amorphous silicon, monocrystalline silicon-germanium, polycrystalline silicon-germanium, carbon-doped silicon, or a combination thereof.

The device layer 110 may include silicon oxide, silicon nitride, silicon oxynitride, low-k dielectrics, high-k dielectrics, or a combination thereof. The device layer 110 may include an insulating material having excellent step coverage and gap fill properties. In one embodiment, the device layer 110 may include an oxide such as tetraethyl orthosilicate (TEOS) or borophosphosilicate glass (BPSG).

The wiring structure 120 may be disposed in the chip region CR. The wiring structure 120 may penetrate the device layer 110.

The wiring structure 120 may include a wiring layer 121. A plurality of interconnect wiring layers and interconnect wiring contacts connecting the plurality of interconnect wiring layers may be disposed below the wiring layer 121. The wiring layer 121 may be disposed on the device layer 110. In one embodiment, the wiring layer 121 may include aluminum (Al).

A protective layer 122 may be disposed on the device layer 110 in the chip region CR. The protective layer 122 may be disposed to cover the wiring layer 121. The protective layer 122 may include a silicon nitride film or a silicon oxynitride film. In one embodiment, the protective layer 122 may be formed of TEOS.

A passivation layer 131 may be disposed on the protective layer 122. The passivation layer 131 may include a high-density plasma oxide, a nitride, or a combination thereof. The passivation layer 131 may include a passivation oxide layer 132 and a passivation nitride layer 133. The passivation nitride layer 133 may be disposed on the passivation oxide layer 132. In one embodiment, the passivation oxide layer 132 may include the high-density plasma oxide.

A redistribution insulating layer 134 may be disposed on the passivation layer 131. The redistribution insulating layer 134 may include silicon oxide, silicon nitride, silicon oxynitride, low-k dielectrics, high-k dielectrics, or a combination thereof. In one embodiment, the redistribution insulating layer 134 may include an oxide.

An insulating structure 130 may be defined to include the passivation layer 131 and the redistribution insulating layer 134. The insulating structure 130 may be disposed on the substrate 101.

The first trench segments T1s may be disposed on the device layer 110 in the scribe lane region SR. The first trench segments T1s may be disposed at the same level as the insulating structure 130. The first trench segments T1s may penetrate the insulating structure 130. A lower surface of each first trench segment T1s may contact an upper surface of the device layer 110. A distance between the lower surface of the first trench segments T1s and an upper surface of the substrate 101 may be smaller than a distance between the lower surface of the second trench T2 and the upper surface of the substrate 101. An alignment pattern layer 143k may be disposed inside the first trench segments T1s (particularly, the conductive layer 143c including a first portion 143c1 and a second portion 143c2).

Although the alignment pattern layer 143k is illustrated as being disposed on only the portion of the side surfaces of the first trench segments T1s, the present disclosure is not limited thereto, and the alignment pattern layer 143k may also be disposed on a portion of the bottom surface of the first trench segments T1s.

A conductive layer 143c may be disposed on the insulating structure 130 in the scribe lane region SR. At least a portion of the conductive layer 143c may overlap the insulating structure 130 in an area between areas where the first trench segments T1s are disposed. The conductive layer 143c may include the first portion 143c1 and the second portion 143c2. The first portion 143c1 may overlap the insulating structure 130 in areas other than the areas in which the first trench segments T1s are disposed.

A distance between the second portion 143c2 and the chip region CR may be greater than a distance between the first portion 143c1 and the chip region CR. An uppermost surface of the second portion 143c2 may be at a level higher than an upper surface of the insulating structure 130. A lower surface of the second portion 143c2 may be positioned on the same plane as lower surfaces of the plurality of first trench segments T1s.

Since the conductive layer 143c is disposed on the insulating structure 130, moisture infiltration may be controlled when the semiconductor chip is molded during a subsequent packaging process.

The second trench T2 may be disposed on the wiring layer 121. A third trench T3 may be located inside the insulating structure 130.

A redistribution pattern layer 142 may be disposed on the insulating structure 130 in the chip region CR. The redistribution pattern layer 142 may include a redistribution trench portion 142tand a redistribution pad portion 142p. The redistribution trench portion 142tmay be located inside the second trench T2. The redistribution pad portion 142pmay be located on the upper surface of the insulating structure 130. The redistribution pattern layer 142 may be disposed at the same level as the conductive layer 143c.

A capping layer 151 may be disposed on the redistribution pattern layer 142. The capping layer 151 may be located on the insulating structure 130. In one embodiment, the capping layer 151 may include a nitride.

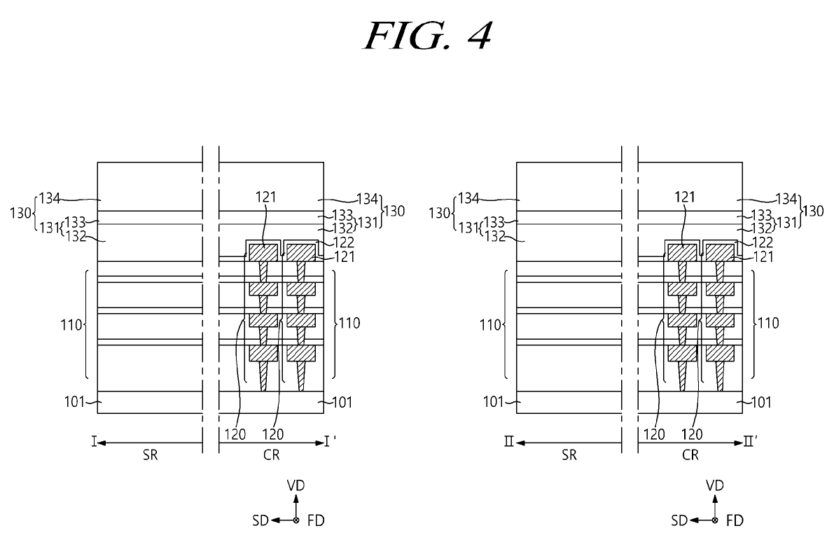

FIGS. 4-6 are cross-sectional views illustrating a method of manufacturing a semiconductor device according to the embodiment disclosed in FIG. 2.

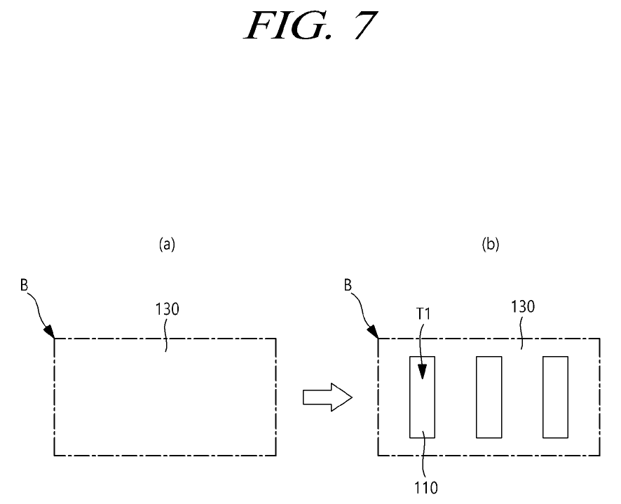

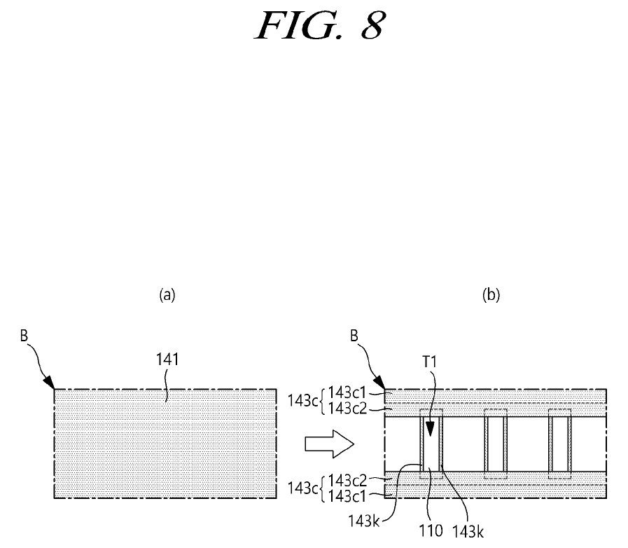

FIGS. 7 and 8 are plan views illustrating a method of manufacturing a semiconductor device according to the embodiment disclosed in FIG. 2, and show an enlarged view of region B of FIG. 2.

Referring to FIGS. 4 and 7(a) , the device layer 110 may be formed on the substrate 101. The wiring structure 120 may be formed on the substrate 101. The wiring structure 120 may be formed in the chip region CR. The wiring structure 120 may penetrate the device layer 110.

On the device layer 110 in the chip region CR, the protective layer 122 and the passivation layer 131 may be sequentially formed. The protective layer 122 may be formed to cover the wiring layer 121. The passivation nitride layer 133 may be formed on the passivation oxide layer 132.

The passivation layer 131 may be formed on the device layer 110 in the scribe lane region SR. A redistribution insulating layer 134 may be formed on the passivation layer 131.

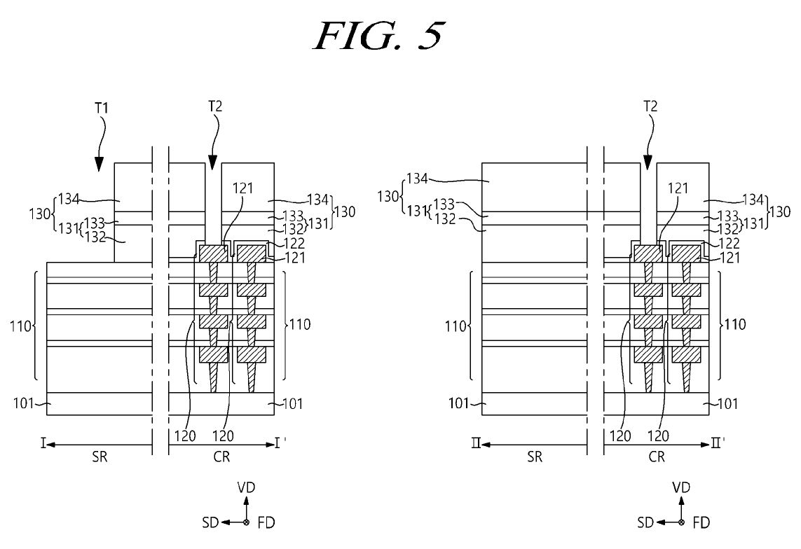

Referring to FIGS. 5 and 7(b) , a first trench T1 may be formed in the scribe lane region SR. The first trench T1 may be formed by etching the insulating structure 130. In one embodiment, the first trench T1 may be formed through a dry etching process. The first trench T1 may be formed to penetrate the insulating structure 130. During the formation of the first trench T1, the portion of the upper surface of the device layer 110 may be exposed. The lower surface of the first trench T1 may be formed to be in contact with the upper surface of the device layer 110.

The second trench T2 may be formed in the chip region CR. The second trench T2 may be formed by etching the insulating structure 130. In one embodiment, the second trench T2 may be formed in the same manner as the first trench T1. During the formation of the second trench T2, the portion of the upper surface of the wiring layer 121 may be exposed. The lower surface of the second trench T2 may be formed to be in contact with the upper surface of the wiring layer 121.

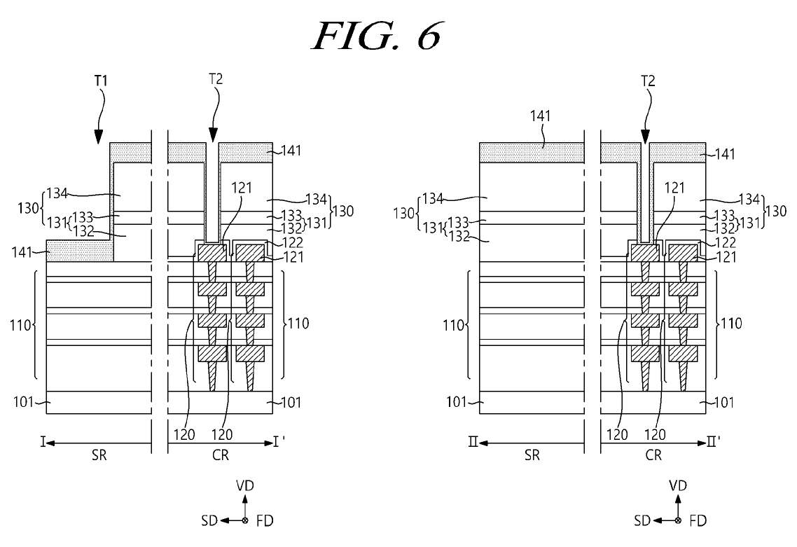

Referring to FIGS. 6 and (a) of 8 , a redistribution material 141 may be deposited on the insulating structure 130. The redistribution material 141 may be deposited to cover the first trench T1 and the second trench T2.

The redistribution material 141 may be formed using a film-forming technique with excellent step coverage, such as chemical vapor deposition (CVD), physical vapor deposition (PVD), or atomic layer deposition (ALD). In one embodiment, the redistribution material 141 may be deposited by physical vapor deposition (PVD). A barrier material (not shown) may be deposited before depositing the redistribution material 141. In one embodiment, the barrier material may include titanium nitride (TiN).

When the redistribution material 141 is deposited, an overhang may be formed. The redistribution material 141 may include a conductive metal such as copper (Cu) or aluminum (Al). In one embodiment, the redistribution material 141 may include aluminum (Al).

Referring to FIGS. 3 and (b) of 8 , the redistribution material 141 may be etched. A conductive layer 143c and a alignment pattern layer 143k may be formed in the scribe lane region SR. The redistribution pattern layer 142 may be formed in the chip region CR. The redistribution pattern layer 142 may include the same material as the conductive layer 143c. In one embodiment, the redistribution pattern layer 142 may include aluminum (Al).

If all the redistribution material 141 in the alignment key region B is etched, abnormal dicing may occur due to the alignment pattern layer 143k remaining inside the first trench T1. In the present embodiments, since a portion of the redistribution material 141 in the alignment key region B is not etched, it may serve as a buffer even if abnormal dicing occurs. Accordingly, straight dicing may be achieved. Moreover, since a portion of the redistribution material 141 in the alignment key region B is not etched, moisture penetration may be prevented.

The redistribution pattern layer 142 may be formed inside the second trench T2 and on the insulating structure 130. The redistribution trench portion 142tmay be formed inside the second trench T2. The redistribution pad portion 142pmay be formed on the insulating structure 130.

The capping layer 151 may be deposited on the redistribution pattern layer 142. In one embodiment, the capping layer 151 may include a nitride. After the capping layer 151 is deposited, the portion of the upper surface of the redistribution pad portion 142p may be exposed through an etching process.

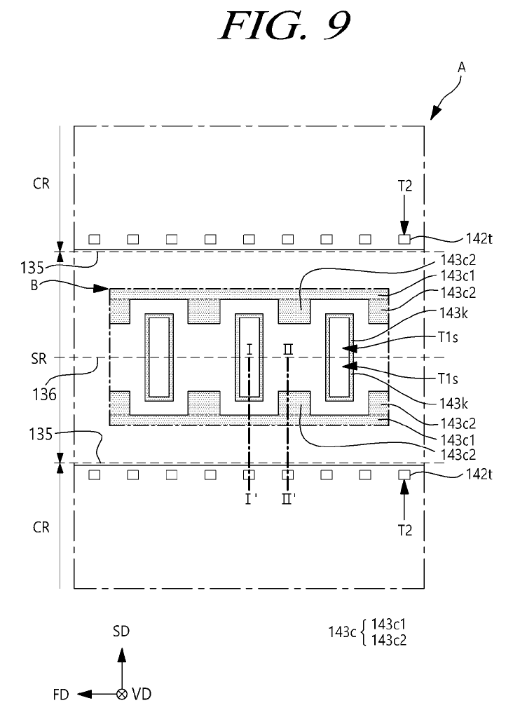

FIG. 9 is a plan view illustrating another embodiment of a semiconductor device disclosed in FIG. 1, and shows an enlarged view of region A of FIG. 1.

The semiconductor device shown in FIG. 9 may be formed by the same method as the one described with reference to FIGS. 4-7,6 and (a) of 8, .

In the following embodiments, descriptions of components that are substantially the same as those in the previous embodiments will be omitted.

Referring to FIG. 9, the conductive layer 143c may include the first portion 143c1 and the second portion 143c2. One side of the first portion 143c1 may respectively correspond to sides of the plurality of first trench segments T1s that face the chip region CR. For example, the plurality of first trench segments T1s may face the chip region CR of the semiconductor device and the chip region CR of the adjacent semiconductor device. The first portion 143c1 may be spaced apart from the first trench segments T1s in the second direction SD. The second portion 143c2 may be spaced apart from the first trench segments T1s in the first direction FD. At least a part of the second portion 143c2 may be disposed in a region between the first trench segments T1s.

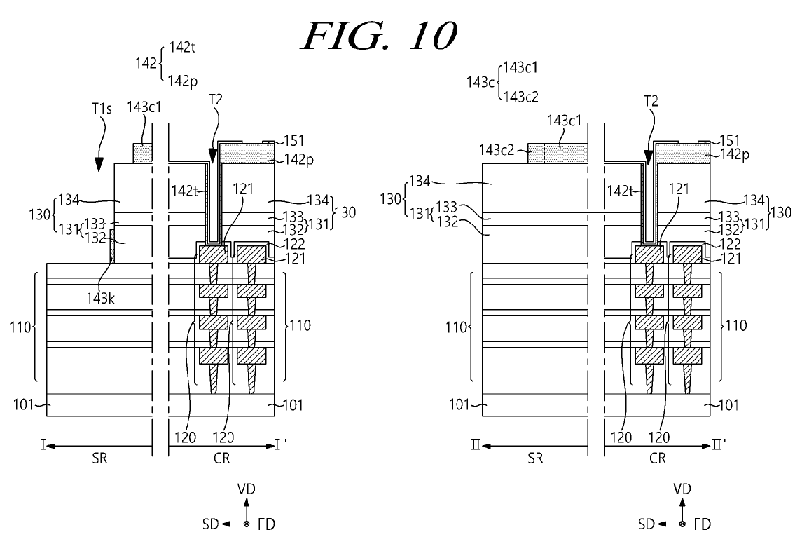

FIG. 10 is a cross-sectional view illustrating an example of section I-I′ of FIG. 8.

Referring to FIG. 10, the alignment pattern layer 143k may be disposed on a side surface of the first trench segment T1s. The first portion 143c1 may be disposed on the insulating structure in the scribe lane region SR.

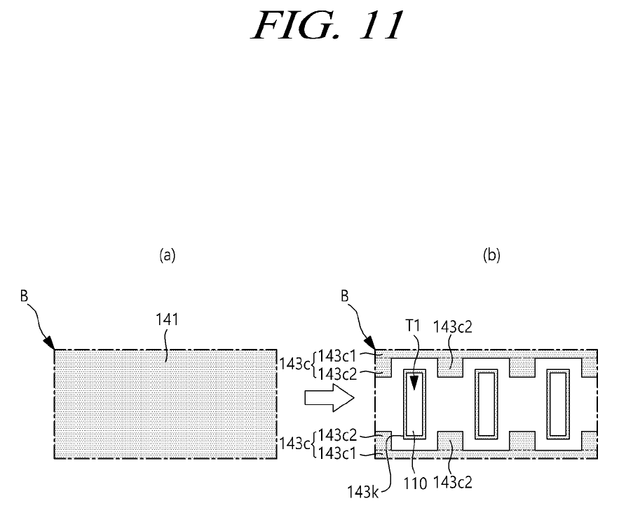

FIG. 11 is a plan view illustrating a method of manufacturing a semiconductor device according to the embodiment disclosed in FIG. 8, and shows an enlarged view of region B of FIG. 8.

Referring to FIGS. 6 and 11(a) the redistribution material 141 may be deposited on the insulating structure 130. The redistribution material 141 may be deposited to cover the first trench T1 and the second trench T2.

Referring to FIGS. 10 and 11(b) , the redistribution material 141 may be etched. The alignment pattern layer 143kmay be formed inside the first trench T1. Since not all of the redistribution material 141 in the alignment key region B is etched, even if abnormal dicing occurs, the first portion 143c1 may allow the dicing process to proceed in a straight manner. Since at least a part of the second portion 143c2 is disposed between adjacent first trenches T1, the dicing process may still proceed in a straight manner even if the dicing path changes.

The foregoing description is merely illustrative of the technical spirit of the present disclosure, and it will be understood by those of ordinary skill in the art that various modifications and alterations can be made without departing from the essential characteristics of the present disclosure. Furthermore, the embodiments disclosed herein are provided for illustrative purposes and are not intended to limit the technical spirit of the present disclosure, and the scope of the present disclosure should not be construed as being limited by such embodiments.

What is claimed is:

1. A semiconductor device comprising:
a substrate including a chip region and a scribe lane region disposed outside the chip region;
an insulating structure disposed on the substrate;
a plurality of trench segments disposed to penetrate the insulating structure in the scribe lane region, and arranged, in first areas, along a first direction parallel to a first boundary between the chip region and the scribe lane region; and
a conductive layer at least partially overlapping the insulating structure in second areas between the first areas.

2. The semiconductor device according to claim 1,
wherein the conductive layer comprises a first portion and a second portion in contact with the first portion, and
wherein the second portion is disposed between the first portion and a second boundary disposed apart from the first boundary in the scribe lane region.

3. The semiconductor device according to claim 2,
wherein the second portion is disposed to extend in the first direction.

4. The semiconductor device according to claim 3,
wherein the second portion is disposed to overlap at least a portion of the plurality of trench segments.

5. The semiconductor device according to claim 4,
wherein the second portion is disposed to completely cover sides of the plurality of trench segments, which face the chip region.

6. The semiconductor device according to claim 5,
wherein an uppermost surface of the second portion is at a level higher than an upper surface of the insulating structure.

7. The semiconductor device according to claim 3,
wherein the first portion and the second portion have a same width in the first direction.

8. The semiconductor device according to claim 2,
wherein one side of the first portion corresponds to sides of the plurality of trench segments, which face the chip region.

9. The semiconductor device according to claim 2,
wherein the plurality of trench segments are disposed between one end and the other end of the conductive layer.

10. The semiconductor device according to claim 1,
further comprising a redistribution pattern layer disposed in the chip region at a same level as the conductive layer, the redistribution pattern layer comprising a same material as the conductive layer.

11. A semiconductor device comprising:
a substrate including a chip region and a scribe lane region disposed outside the chip region;
an insulating structure disposed on the substrate;
a plurality of trench segments disposed in the scribe lane region at a same level as the insulating structure, and arranged, in first areas, along a first direction parallel to a first boundary between the chip region and the scribe lane region; and
a conductive layer disposed on the insulating structure in the scribe lane region,
wherein the conductive layer comprises:
a first portion disposed between the first boundary and a second boundary, and spaced farther from a second boundary than the plurality of trench segments, the first portion extending in a direction parallel to the first direction, the second boundary being disposed apart from the first boundary in the scribe lane region; and
a second portion at least partially overlapping the insulating structure in second areas between the first areas.

12. The semiconductor device according to claim 11,
wherein the second portion is disposed to be contact with the first portion and disposed between the first portion and the second boundary.

13. The semiconductor device according to claim 12,
wherein the second portion is disposed to extend in the first direction.

14. The semiconductor device according to claim 13,
wherein the second portion is disposed to overlap at least a portion of the plurality of trench segments.

15. The semiconductor device according to claim 14,
wherein the second portion is disposed to completely cover sides of the plurality of trench segments, which face the chip region.

16. The semiconductor device according to claim 15,
wherein an uppermost surface of the second portion is at a level higher than an upper surface of the insulating structure.

17. The semiconductor device according to claim 13,
wherein the first portion and the second portion have a same width in the first direction.

18. The semiconductor device according to claim 12,
wherein one side of the first portion corresponds to sides of the plurality of trench segments, which face the chip region.

19. The semiconductor device according to claim 12,
wherein the plurality of trench segments are disposed between one end and the other end of the conductive layer.

20. The semiconductor device according to claim 11,
further comprising a redistribution pattern layer disposed in the chip region at a same level as the conductive layer, the redistribution pattern layer comprising a same material as the conductive layer.
